(19) United States
(12) Patent Application Publication
(10) Pub. No.: US 2026/0178689 A1
(43) Pub. Date: Jun. 25, 2026

(54) CALCULATION APPARATUS, METHOD AND PROGRAM

(71) Applicant: RIGAKU CORPORATION, Tokyo (JP)

(72) Inventors: Masatsugu YOSHIMOTO, Tokyo (JP); Kazuhiko OMOTE, Tokyo (JP)

(73) Assignee: RIGAKU CORPORATION, Tokyo (JP)

(21) Appl. No.: 19/368,038

(22) Filed: Oct. 24, 2025

(30) Foreign Application Priority Data
Dec. 23, 2024 (JP) 2024-226055

(51) Int. Cl. G06F 17/15; G06F 30/20

(52) U.S. Cl. CPC G06F 17/15; G06F 30/20

(57) ABSTRACT

A calculation apparatus for calculating a correlation function from a structural model comprises a structural model acquiring section for acquiring the structural model including a plurality of types of atoms in space, an atomic species setting section for setting a specific atomic species in the structural model, and a correlation function calculating section for calculating the correlation function that is a ratio between a first radial distribution function and a second radial distribution function, wherein the first radial distribution function is a radial distribution function between atoms of the specific atomic species and atoms of the specific atomic species, and the second radial distribution function is a radial distribution function between atoms of the specific atomic species and atoms of two or more types of atomic species including the specific atomic species.

### CROSS-REFERENCE TO RELATED APPLICATION

This application claims priority from Japanese Patent Application No. 2024-226055 filed on Dec. 23, 2024, the entire contents of which are incorporated herein by reference.

### FIELD

The present disclosure relates to a calculation apparatus, method, and program for calculating a correlation function from a structural model.

### DESCRIPTION OF RELATED ART

In recent years, with the development of analytical methods such as an RMC method, the range larger than the unit cell can be made the range of the analysis. As a result, information which was not obtained by the conventional analysis using the unit cell can be obtained. One of the pieces of information is information on the particle position in the structural model.

However, conventionally, there has been no method for evaluating the mixing state of the adjacent atoms of the structural model, since it is only discussed by using the pair distribution function g(r) of the partial correlation calculated from the estimated structural model. Such information is important because the knowledge of the mixing state of the adjacent atoms in the structural model leads to a better understanding of the properties of the material.

Non-Patent Document 1 discloses a method for estimating S(Q) in a mixed state of two-element systems from actual measurement data. Thermodynamic formulas have also been disclosed that can be used to investigate the concentration and temperature dependence of various types of mixtures (regular, ordered-disordered, thermally disordered, etc.).

Non-Patent Document 2 discloses a method for analyzing the dipole correlation of water in the presence of simple ionic solutes using molecular dynamics simulations and empirical potentials. In this analysis method, the dipole correlation of water is defined as a function of temperature and density. In Non-Patent Document 2, a spatial correlation function of a dipole-dipole is defined, and its characteristics are discussed.

### Non-Patent Document

Non-Patent Document 1: A. B. Bhatia, D. E. Thornton, Phys. Rev. B 2 (1970) 3004-3012. https://doi.org/10.1103/PhysRevB.2.3004.
Non-Patent Document 2: C. Zhang, G. Galli, J. Chem. Phys. 141 (2014) 084504 (5 pp). https://doi.org/10.1063/1.4893638.

### SUMMARY

However, in the methods described in Non-Patent Document 1 and Non-Patent Document 2, it is not taken into account that expression of a mixed state of adjacent atoms of a structural model.

As a result of intensive research, the present inventors have discovered that it is possible to express a mixed state of adjacent atoms of a structural model by calculating two types of radial distribution functions by focusing on a specific atomic species and then calculating a correlation function, which is the ratio of the two types of radial distribution functions. Further, it has been found that the mixed state of the adjacent atoms of the structural model can be evaluated by analyzing the calculated correlation function, and the present disclosure has been completed.

The present disclosure has been made in view of such circumstances, and an object of the present disclosure is to provide a calculation apparatus, method and program for calculating a correlation function from a structural model.

(1) In order to achieve the above object, the calculation apparatus of the present disclosure has the following means. That is, a calculation apparatus according to an aspect of the present invention is a calculation apparatus for calculating a correlation function from a structural model, the calculation apparatus comprising a structural model acquiring section for acquiring the structural model including a plurality of types of atoms in space, an atomic species setting section for setting a specific atomic species in the structural model, and a correlation function calculating section for calculating the correlation function that is a ratio between a first radial distribution function and a second radial distribution function, wherein the first radial distribution function is a radial distribution function between atoms of the specific atomic species and atoms of the specific atomic species, and the second radial distribution function is a radial distribution function between atoms of the specific atomic species and atoms of two or more types of atomic species including the specific atomic species.

(2) Further, the calculation apparatus according to an aspect of the present disclosure further comprises a display section for displaying the correlation function.

(3) Further, in the calculation apparatus according to an aspect of the present disclosure, the display section displays the correlation function and an atomic ratio of the specific atomic species in the structural model in an overlapping manner.

(4) Further, in the calculation apparatus according to one aspect of the present disclosure, the display section simultaneously displays the correlation function of the specific atomic species and the correlation function of an atomic species different from the specific atomic species.

(5) Further, in the calculation apparatus according to an aspect of the present disclosure, a plane determining section for determining a specific plane in the structural model, wherein the correlation function calculating section calculates the correlation function in the specific plane.

(6) Further, the calculation apparatus according to an aspect of the present disclosure further comprises an evaluation section for evaluating the regularity of the atomic arrangement in the structural model based on the correlation function.

(7) Further, the calculation apparatus according to an aspect of the present disclosure further comprises an index calculating section for calculating an index based on the correlation function, wherein the evaluation section evaluates the regularity of the atomic arrangement based on the index.

(8) Further, in the calculation apparatus according to an aspect of the present disclosure, the index is a variance or a standard deviation of the correlation function.

(9) Further, in the calculation apparatus according to an aspect of the present disclosure, the index is calculated based on the correlation function and an atomic ratio of the specific atomic species in the structural model.

(10) Further, in the calculation apparatus according to an aspect of the present disclosure, the structural model is a model generated by a RMC method.

(11) Further, a method according to an aspect of the present disclosure is a method of calculating a correlation function from a structural model, the method comprising acquiring the structural model including a plurality of types of atoms in space, setting a specific atomic species in the structural model, and calculating the correlation function that is a ratio between a first radial distribution function and a second radial distribution function, wherein the first radial distribution function is a radial distribution function between atoms of the specific atomic species and atoms of the specific atomic species, and the second radial distribution function is a radial distribution function between atoms of the specific atomic species and atoms of two or more types of atomic species including the specific atomic species.

(12) Further, a program according to an aspect of the present disclosure is a program for calculating a correlation function from a structural model, the program causing a computer to execute processing comprising acquiring the structural model including a plurality of types of atoms in space, setting a specific atomic species in the structural model, and calculating the correlation function that is a ratio between a first radial distribution function and a second radial distribution function, wherein the first radial distribution function is a radial distribution function between atoms of the specific atomic species and atoms of the specific atomic species, and the second radial distribution function is a radial distribution function between atoms of the specific atomic species and atoms of two or more types of atomic species including the specific atomic species.

### BRIEF DESCRIPTION OF THE DRAWINGS

FIG. 1 is a block diagram showing an example of a configuration of a calculation apparatus according to a first embodiment.

FIG. 2 is a block diagram showing a modification of the configuration of the calculation apparatus according to the first embodiment.

FIG. 3 is a flowchart showing an example of an operation of the calculation apparatus according to the first embodiment.

FIG. 4 is a block diagram showing an example of a configuration of a calculation apparatus according to a second embodiment.

FIG. 5 is a flowchart showing an example of an operation of the calculation apparatus according to the second embodiment.

FIG. 6 is a block diagram showing an example of a configuration of a calculation apparatus according to a third embodiment.

FIG. 7 is a block diagram showing a modification of the configuration of the calculation apparatus according to the third embodiment.

FIG. 8 is a flowchart showing an example of an operation of the calculation apparatus according to the third embodiment.

FIG. 9 is a block diagram showing an example of a configuration of a calculation apparatus according to one or more aspects of the present disclosure.

FIG. 10 is a schematic diagram showing an example of a configuration of a system.

FIG. 11 is a block diagram showing an example of a configuration of a control apparatus.

FIG. 12A and FIG. 12B are schematic diagrams showing exemplary states of structural model 1 and structural model 2, respectively.

FIG. 13A and FIG. 13B are graphs of the pair distribution function and the correlation function, respectively, where Ne of structural model 1 is a specific atomic species.

FIG. 14A and FIG. 14B are graphs of the pair distribution function and the correlation function, respectively, where Ar of structural model 1 is a specific atomic species.

FIG. 15A and FIG. 15B are graphs of the pair distribution function and the correlation function, respectively, where Ne of structural model 2 is a specific atomic species.

FIG. 16A and FIG. 16B are graphs of the pair distribution function and the correlation function, respectively, where Ar of structural model 2 is a specific atomic species.

FIG. 17 is a schematic diagram showing an example of a state of structural model 3.

FIG. 18A and FIG. 18B are graphs of the pair distribution function and the correlation function, respectively, where Ne of structural model 3 is a specific atomic species.

FIG. 19A and FIG. 19B are graphs of the pair distribution function and the correlation function, respectively, where Ar of structural model 3 is a specific atomic species.

FIG. 20A and FIG. 20B are schematic diagrams showing the crystallographic structural model and the unit cell of NCM333, respectively.

FIG. 21A and FIG. 21B are graphs of the first radial distribution function and the correlation function, respectively, where each of Ni, Co, Mn of structural model 4 is a specific atomic species.

FIG. 22A and FIG. 22B are graphs of the first radial distribution function and the correlation function, respectively, where each of Ni, Co, Mn of structural model 5 is a specific atomic species.

### DETAILED DESCRIPTION

Next, embodiments of the present disclosure are described with reference to the drawings. In order to facilitate understanding of the description, reference number indicating the same constituent element is used as same and overlapping descriptions are omitted in each drawing.

### First Embodiment

### [Calculation Apparatus]

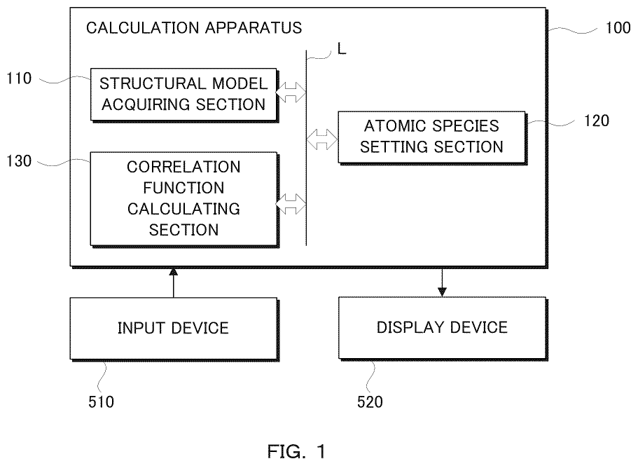

In the first embodiment, a case where a correlation function is calculated from a structural model is described. FIG. 1 is a block diagram showing an example of a configuration of a calculation apparatus 100 according to a first embodiment. The calculation apparatus 100 may be connected to the X-ray diffraction apparatus 200 via a control apparatus 300 for controlling the X-ray diffraction apparatus 200 described below or directly.

The calculation apparatus 100 calculates a correlation function from the structural model. The calculation apparatus 100 is configured by a computer formed by connecting a CPU (Central Processing Unit), a ROM (Read Only Memory), a RAM (Random Access Memory), and a memory to a bus. The calculation apparatus 100 may be a PC terminal or a server on a cloud. Not only the whole apparatus but also part of the apparatus or some functions of the apparatus may be provided on the cloud. The input device 510 and the display device 520 are connected to CPU of the calculation apparatus 100 via an appropriate interface. The input device 510 is, for example, a keyboard or a mouse, and performs input to the calculation apparatus 100. The display device 520 is, for example, a display and displays a structural model, a specific atomic species, an atomic ratio of a specific atomic species, a correlation function, a radial distribution function, a pair distribution function, a specific plane in the structural model, an evaluation of regularity of an atomic arrangement in the structural model, an index, a variance and the like.

The calculation apparatus 100 comprises a structural model acquiring section 110, an atomic species setting section 120, and a correlation function calculating section 130. Each section can transmit and receive information via the control bus L.

The structural model acquiring section 110 acquires a structural model. The structural model acquiring section 110 may acquire information related to a feature of the structural model together with the structural model. The information regarding the feature of the structural model is, for example, information indicating that the structural model has a layered structure. The structural model acquiring section 110 may acquire a structural model directly from an apparatus or software that generates a structural model or may acquire a structural model stored in a storage apparatus or the like. In addition, the calculation apparatus 100 itself may have a function of generating a structural model.

The structural model is a model showing the arrangement of particles (atoms and molecules) in a finite region. The structural model can be given as data indicating the arrangement of a finite number of particles in, for example, a cube, a cuboid or a parallel hexahedron, depending on the sample. In the present disclosure, the structural model is a model including a plurality of types of particles (atoms or molecules).

The structural model to which the present disclosure can be applied may be generated based on measurement data of any apparatus as long as it is a structural model generated by structural modeling in which a crystal structure is an initial structure. For example, the present disclosure is not limited to a structural model generated based on total scattering data measured by an X-ray diffraction apparatus and can be applied to a structural model generated based on measurement data measured by a probe similar thereto. Specifically, the present disclosure can be applied to a structural model generated on the basis of, for example, measurement data by synchrotron radiation and measurement data by particle beams such as neutron beams and electron beams.

The structural model may be generated by an RMC method (Reverse Monte Carlo). The RMC method is a method for estimating a structural model that reproduces an actual measurement value by varying arrangement of atoms (or molecules) by a given structural model using a random number. The RMC has a wide search space and can obtain a global minimum solution, which is useful as a solution for complicated optimization. When the RMC method is applied to the present disclosure, a structural model that reproduces measurement data is likely to be obtained, and a correlation function calculated based on the structural model is likely to be a meaningful function for understanding the measurement data. The method of generating the structural model is not limited to the RMC method. The structural model can also be generated, for example, by an MD (molecular dynamics) or an MC (Monte Carlo method).

The atomic species setting section 120 sets a specific atomic species in the structural model. A specific atomic species is one of the types of atoms for which a correlation function in a structural model is to be calculated. The setting of the specific atomic species may be performed according to an instruction of the user.

The correlation function calculating section 130 calculates a correlation function that is a ratio of the first radial distribution function to the second radial distribution function. The first radial distribution function is a radial distribution function between atoms of a specific atomic species and atoms of a specific atomic species. The second radial distribution function is a radial distribution function between atoms of a specific atomic species and atoms of two or more types of atomic species including the specific atomic species in the structural model. Two or more types of atomic species including the specific atomic species in the structural model may be a part of atomic species in the structural model or may be all the atomic species. The correlation function is defined using the ratio between the first radial distribution function and the second radial distribution function, and the distance dependence of density fluctuation of atomic species can be expressed by this correlation function.

The radial distribution function is a function that indicates the distribution of atoms and defines the distribution of atoms located around certain atoms as a function of distance when the certain atoms are focused on. That is, the first radial distribution function is a function that focuses on atoms of a particular atomic species and indicates the distribution of atoms of the same atomic species located around those atoms. In addition, the second radial distribution function is a function that focuses on atoms of the specific atomic species and indicates the distribution of atoms of two or more selected atomic species including the specific atomic species located around those atoms.

Two or more types of selected atomic species including a specific atomic species are described by way of example. For example, when the atomic species included in the structural model is A, B and C and the specific atomic species is A, the selected two or more atomic species including the specific atomic species are any of A and B, A and C, and A, B and C.

A is treated as a specific atomic species, N_{A A}(r) is treated as the first radial distribution function, and N_{AX}(r) is treated as the second radial distribution function. At this time, the first radial distribution function N_{AA}(r) is expressed by the following Formula (1), for example. In addition, the second radial distribution function N_{AX}(r) is expressed by the following Formula (2), for example. Where r is the distance, N_{A} is the number of A, δ is the delta function, rᵢⱼ is the distance between the ith A and jth A or the selected atomic species, and N is the number of selected two or more atomic species including the specific atomic species.

$${N}_{AA} ( r ) = {\sum }_{i = 1}^{{N}_{A}} {\sum }_{j = 1}^{{N}_{A}} δ ( {r}_{ij} - r ) \qquad ( 1 )$$

$${N}_{AX} ( r ) = {\sum }_{i = 1}^{{N}_{A}} {\sum }_{j = 1}^{{N}_{A}} δ ( {r}_{ij} - r ) \qquad ( 2 )$$

The definition formulas of the first radial distribution function and the second radial distribution function are not limited to Formulas (1) and (2). For example, the delta function may be replaced with a function, such as a Gaussian distribution, that indicates the probability of existence of a specific atomic species or two or more selected atomic species including a specific atomic species.

N_{AA}(r) is treated as the first radial distribution function, N_{AX}(r) is treated as the second radial distribution function, and C_{A}(r) is treated as the correlating function. In this case, the correlation function C_{A}(r) can be expressed by the following Formula (3), for example. Note that the definition formula of the correlation function is not limited to Formula (3). The correlation function may be any expression including a ratio of the first radial distribution function to the second radial distribution function. On the other hand, by defining the correlation function C_{A}(r) as shown in Formula (3), the upper limit of the correlation function C_{A}(r) becomes 1. When C_{A}(r) is 1, it is known that there is only a set of specific atomic species in the correlation distance r, and therefore, the correlation function may be defined to have such a property.

$${C}_{A} ( r ) = \frac{{N}_{AA} ( r )}{{N}_{AX} ( r )} \qquad ( 3 )$$

In the above description, the correlation function is defined as the ratio of the first radial distribution function to the second radial distribution function. However, the correlation function need not necessarily be defined as the ratio of the first radial distribution function to the second radial distribution function. For example, it can be defined as the ratio of the pair distribution function for a specific atomic species.

Specifically, A is treated as a specific atomic species, g_{AA}(r) is treated as the pair distribution function (first pair distribution function) of only A centered at A, and g_{AX}(r) is treated as the pair distribution function (second pair distribution function) of two or more selected atomic species including A centered at A. At this time, the same correlation function C_{A}(r) as in Formula (3) can also be defined by Formula (4) below. This is because the radial distribution function N(r) and the pair distribution function g(r) have a relationship represented by the following Formula (5). Where ρ is the average density of the structural model.

$${C}_{A} ( r ) = \frac{{g}_{AA} ( r )}{{g}_{AX} ( r )} \qquad ( 4 )$$

$$N ( r ) = 4 π {r}^{2} ρ g ( r ) \qquad ( 5 )$$

Thus, if the correlation function is defined as the ratio of the pair distribution function for a specific atomic species, the correlation function can also be said to be the ratio of the first radial distribution function to the second radial distribution function. The calculation of the correlation function may be performed after the calculation of the radial distribution function or the pair distribution function or may be performed directly from the definition formula itself without calculating the radial distribution function or the pair distribution function.

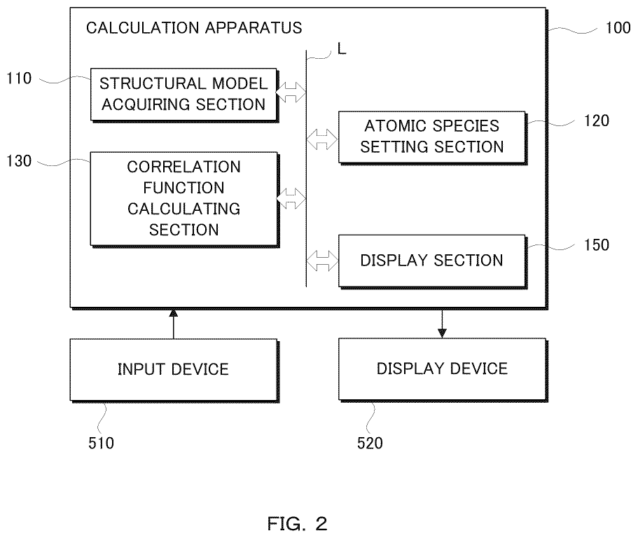

FIG. 2 is a block diagram showing a modification of the configuration of the calculation apparatus 100 according to the first embodiment. As shown in FIG. 2, the calculation apparatus 100 may further comprises a display section 150 in addition to the structural model acquiring section 110, the atomic species setting section 120 and the correlation function calculating section 130. The display section 150 causes the display device 520 to display a correlation function. Further, the display section 150 may display a structural model, a specific atomic species, an atomic ratio of a specific atomic species, a radial distribution function (a first radial distribution function or a second radial distribution function), a pair distribution function (a first pair distribution function or a second pair distribution function), a specific plane in the structural model and an evaluation of regularity, an index, a variance, and the like of an atomic arrangement in the structural model.

The display section 150 may displays the correlation function and the atomic ratio of the specific atomic species in the structural model in an overlapping manner. The atomic ratio of the specific atomic species in the structural model may be the atomic ratio of the specific atomic species to two or more atomic species including the specific atomic species selected in calculating the second radial distribution function. The atomic ratio of the specific atomic species in the structural model may be the atomic ratio of the specific atomic species to any two or more atomic species including the specific atomic species. In this way, the feature of the correlation function with respect to the average concentration of the specific atomic species can be recognized by displaying the correlation function and the atomic ratio of the specific atomic species in the structure model in an overlapped manner.

The display section 150 may simultaneously displays a correlation function of a specific atomic species and a correlation function of an atomic species (also referred to as a second specific atomic species) different from the specific atomic species. As a result, the features of the correlation function for each atomic species can be compared, and the features of the coincidence points and the different points can be recognized.

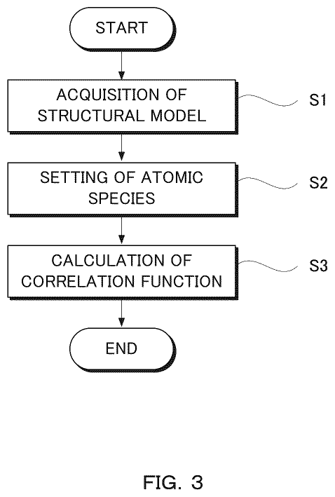

FIG. 3 is a flowchart showing an example of an operation of the calculation apparatus 100 according to the first embodiment. FIG. 3 shows an example of an operation in a case where a correlation function is calculated from a structural model. First, the calculation apparatus 100 acquires the structural model by the structural model acquiring section 110 (step S1). Next, the atomic species setting section 120 sets a specific atomic species in the structural model acquired by the structural model acquiring section 110 (step S2). Then, the correlation function calculating section 130 calculates a correlation function (step S3). If necessary, the correlation function may be output. Further, a radial distribution function or a pair distribution function may be output. In this way, a correlation function can be calculated from the structural model.

When the calculation apparatus 100 comprises the display section 150, a correlation function, a radial distribution function, or a pair distribution function may be displayed as necessary. In this way, the features of the correlation function calculated from the structural model can be captured. Since the correlation function is correspondent to a function representing the mixing state of the neighboring particles of the structural model, the mixing state of the neighboring particles of the structural model can be described by analyzing the correlation function.

### Second Embodiment

### [Calculation Apparatus]

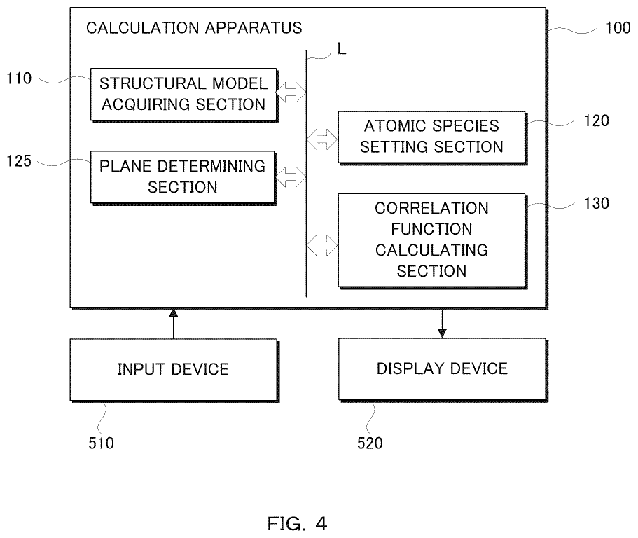

In the second embodiment, a case is described in which a correlation function is calculated for a specific plane in a structural model. FIG. 4 is a block diagram showing an example of a configuration of the calculation apparatus 100 according to the second embodiment. As shown in FIG. 4, the calculation apparatus 100 may further comprises a plane determining section 125 in addition to the structural model acquiring section 110, the atomic species setting section 120 and the correlation function calculating section 130.

The plane determining section 125 determines a specific plane in the structural model. A specific plane is a plane of which a correlation function in a structural model is to be calculated. By determining a specific plane, the mixing state of the neighboring particles present in the specific plane can be analyzed. Determination of a specific plane may be performed according to an instruction of a user. In addition, in a case where the structural model is accompanied by information on the features of the structural model, an option of determining whether or not to determine a specific plane may be provided to the user based on the information.

When the plane determining section 125 determines a specific plane, the correlation function calculating section 130 calculates a correlation function in the specific plane. The correlation function in a specific plane is a correlation function that is a ratio of the first radial distribution function to the second radial distribution function in a specific plane. When the plane determining section 125 does not determine a specific plane, the correlation function calculating section 130 calculates a correlation function in the entire structural model.

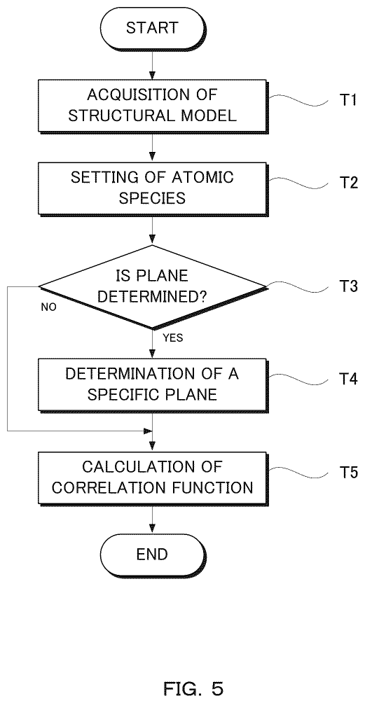

FIG. 5 is a flowchart showing an example of an operation of the calculation apparatus 100 according to the second embodiment. FIG. 5 shows an example of an operation when it is determined whether to determine a specific plane. First, the calculation apparatus 100 acquires a structural model by the structural model acquiring section 110 (step T1). Next, the atomic species setting section 120 sets a specific atomic species in the structural model acquired by the structural model acquiring section 110 (step T2).

Next, it is determined whether or not a specific plane is to be determined (step T3). When a specific plane is determined (step T3—YES), the plane determining section 125 determines the specific plane (step T4). Then, the correlation function calculating section 130 calculates a correlation function (step T5). On the other hand, when a specific plane is not determined (step T3—NO), the correlation function calculating section 130 calculates a correlation function (step T5). If necessary, a correlation function, a specific plane, a radial distribution function, or a pair distribution function may be output. In addition, when the calculation apparatus 100 comprises the display section 150, they may be displayed as necessary. In this way, the correlation function in the specific plane can be calculated. Note that the determination of the specific plane may be performed before the setting of the specific atomic species.

### Third Embodiment

### [Calculation Apparatus]

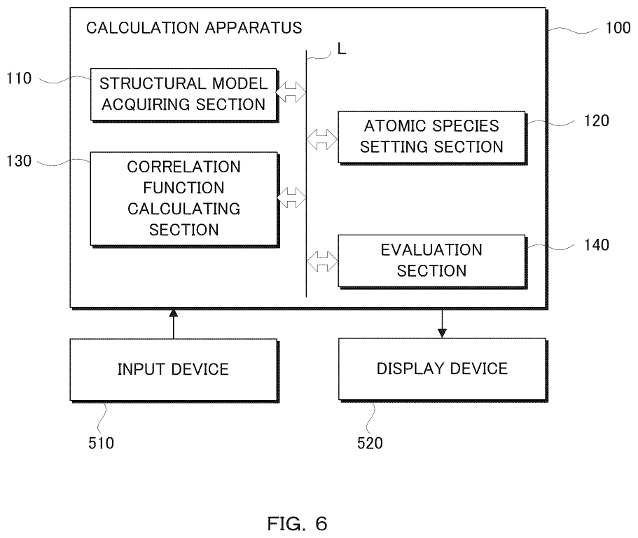

In the third embodiment, the case where the regularity of the atomic arrangement is evaluated based on the correlation function, is described. FIG. 6 is a block diagram showing an example of a configuration of the calculation apparatus 100 according to the third embodiment. As shown in FIG. 6, the calculation apparatus 100 may further comprises an evaluation section 140 in addition to the structural model acquiring section 110, the atomic species setting section 120 and the correlation function calculating section 130.

The evaluation section 140 evaluates the regularity of the atomic arrangement in the structural model based on the correlation function. The regularity of the atomic arrangement in the structural model comprises the viewpoint of whether the atomic arrangement in the structural model is statistically random or not statistically random and has some regularity. The evaluation of the regularity of the atomic arrangement in the structural model may include, for example, an evaluation of whether or not neighboring particles are clustered with each other in a specific atomic species of the structural model. When the correlation distance r is small and the correlation coefficient is larger than the atomic ratio of a specific atomic species, it may be determined that clusters are formed. The evaluation of the regularity of the atomic arrangement in the structural model may be a numerical value calculated based on the correlation function or may be descriptive expression determined based on the features of the correlation function.

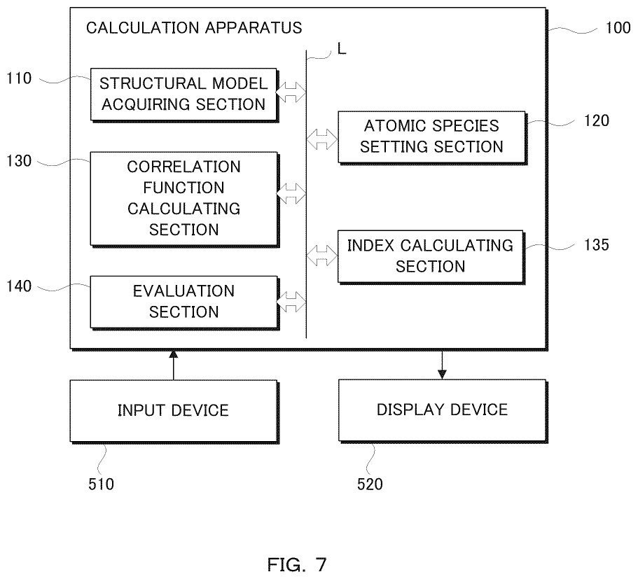

FIG. 7 is a block diagram showing a modification of the configuration of the calculation apparatus 100 according to the third embodiment. As shown in FIG. 7, the calculation apparatus 100 may further comprises an index calculating section 135 in addition to the structural model acquiring section 110, the atomic species setting section 120, the correlation function calculating section 130, and the evaluation section 140.

The index calculating section 135 calculates an index based on the correlation function. When the calculation apparatus 100 comprises the index calculating section 135, the evaluation section 140 evaluates the regularity of the atomic arrangement in the structural model based on the index calculated by the index calculating section 135. The index may be a numerical value that can be used to evaluate the regularity of the atomic arrangement in the structural model. The evaluation section 140 may determine that the index has regularity when the index satisfies a predetermined condition. The predetermined condition varies depending on the type of the index.

The index may be the variance or standard deviation of the correlation function. The correlation function is close to a constant value regardless of the distance in the case of random atomic arrangement. That is, when the deviation from a constant value is large, it is considered that there is some regularity in the atomic arrangement. Therefore, for example, if the variance of the correlation function is larger than a certain value, the atomic arrangement may be evaluated to have regularity, and if the variance of the correlation function is smaller than a certain value, the atomic arrangement may be evaluated as random. Further, for example, when the variance of the correlation function is larger than the variance of the correlation function to be compared, the atomic arrangement has regularity as compared with the atomic arrangement to be compared, and when the variance of the correlation function is smaller than the variance of the correlation function to be compared, the atomic arrangement may be evaluated to be random as compared with the atomic arrangement to be compared. The same applies to the standard deviation. In a case where it is determined that the index has regularity when the index satisfies a predetermined condition, the predetermined condition may be set such that the variance or the standard deviation is a certain value or more. Specific examples in which variance is used as an index are described in detail in Examples.

The index may be calculated based on the correlation function and the atomic ratio of the specific atomic species in the structural model. When the atomic arrangement in the structural model is random, the correlation function approaches the atomic ratio of the specific atomic species in the structural model (hereinafter, the abundance ratio of the specific atomic species). That is, when the abundance rate of the specific atomic species and the value of the correlation function deviate from each other, it can be determined that the atomic arrangement has regularity. When the correlation function is calculated by determining the specific plane, the atomic ratio of the specific atomic species in the specific plane may be treated as the atomic ratio of the specific atomic species in the structure model. When it is determined that there is regularity when the index satisfies the predetermined condition, the predetermined condition may be that the value of the index calculated from the atomic ratio of the specific atomic species and the value of the correlation function is a predetermined value or more.

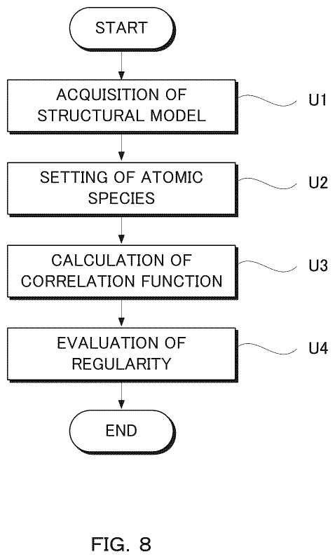

FIG. 8 is a flowchart showing an example of an operation of the calculation apparatus 100 according to the third embodiment. FIG. 8 shows an example of the operation in the case of evaluating the regularity of the atomic arrangement based on the correlation function. First, the calculation apparatus 100 acquires the structural model by the structural model acquiring section 110 (step U1). Next, the atomic species setting section 120 sets a specific atomic species in the structural model acquired by the structural model acquiring section 110 (step U2).

Next, the correlation function calculating section 130 calculates a correlation function (step U3). Then, the evaluation section 140 evaluates the regularity of the atomic arrangement in the structural model (step U4). When the calculation apparatus 100 comprises the index calculating section 135, the index calculating section 135 calculates the index before evaluating the regularity of the atomic arrangement in the structural model. Thereafter, the evaluation section 140 evaluates the regularity of the atomic arrangement based on the index. If necessary, a correlation function, a radial distribution function, a pair distribution function, an evaluation, or an index may be output. In addition, when the calculation apparatus 100 comprises the display section 160, they may be displayed as necessary. In this way, the regularity of the atomic arrangement in the structural model can be evaluated based on the correlation function.

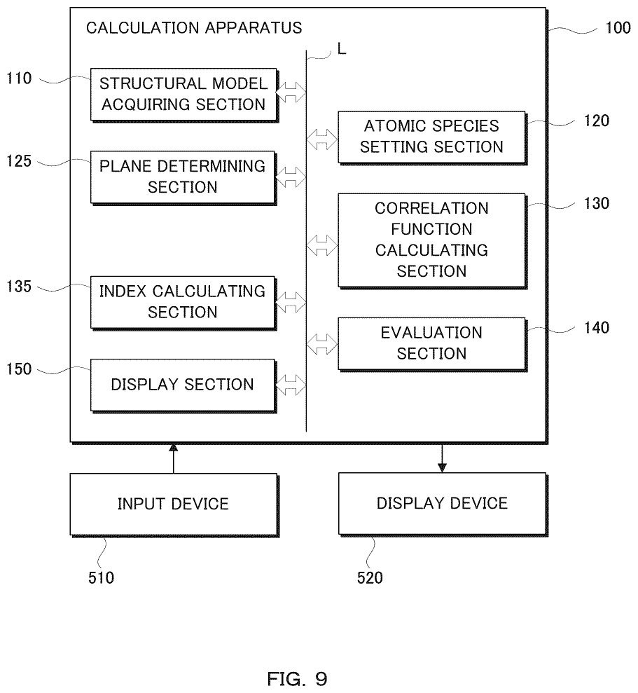

Note that the first to third embodiments may each include some or all of the configurations of the other embodiments. FIG. 9 is a block diagram showing an example of a configuration of the calculation apparatus 100 according to one or more aspects of the present disclosure. As shown in FIG. 9, the calculation apparatus 100 comprises a structural model acquiring section 110, an atomic species setting section 120, a plane determining section 125, a correlation function calculating section 130, an index calculating section 135, an evaluation section 140, and a display section 150. Among these, the plane determining section 125, the index calculating section 135, the evaluation section 140, or the display section 150 are optional components.

### [Whole System]

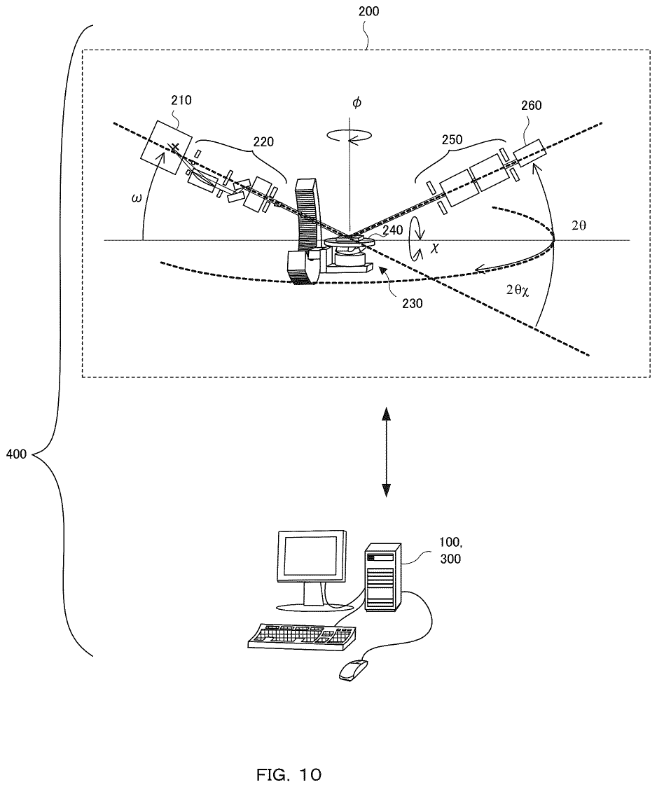

The calculation apparatus 100 or the calculation method of the present disclosure can obtain a structural model and calculate or evaluate a correlation function regardless of the X-ray diffraction apparatus 200 or the control apparatus 300. Therefore, the calculation apparatus 100 does not need to be used at the same time as the X-ray diffraction apparatus 200 or the control apparatus 300. On the other hand, the system may be integrated with the X-ray diffraction apparatus 200 and the control apparatus 300. FIG. 10 is a schematic diagram showing an example of a configuration of a system 400 including a calculation apparatus 100 and an X-ray diffraction apparatus 200. The system 400 comprises a calculation apparatus 100, an X-ray diffraction apparatus 200, and a control apparatus 300.

In FIG. 10, the calculation apparatus 100 and the control apparatus 300 are described as the same PC. However, the calculation apparatus 100 may be configured as an apparatus different from the control apparatus 300. Hereinafter, a case where the calculation apparatus 100 and the control apparatus 300 are configured as different apparatuses is described.

### [X-ray Diffraction Apparatus]

The X-ray apparatus 200 constitutes an optical system that makes X-rays incident on a sample and detects reflected X-rays generated from the sample. The X-ray diffraction apparatus 200 comprises at least an X-ray generating section 210 that generates X-rays from an X-ray focal point or X-ray source, a sample stage 240 on which a sample is located and controls rotation of the sample, and a detector 260 that detects X-rays. The X-ray diffraction apparatus 200 may include an incident-side optical unit 220, a goniometer 230 or an emitting-side optical unit 250. Since the X-ray generating section 210, the incident-side optical unit 220, the goniometer 230, the sample stage 240, the emission-side optical unit 250 and the detector 260 constituting the X-ray diffraction apparatus 200 need only be general, a detailed description thereof is omitted. Incidentally, the configuration shown in FIG. 10 is one example, and thus a variety of other configurations may be adopted.

### [Control Apparatus]

The control apparatus 300 is connected to the X-ray diffraction apparatus 200 to control the X-ray diffraction apparatus 200, and process, store and display of the acquired data.

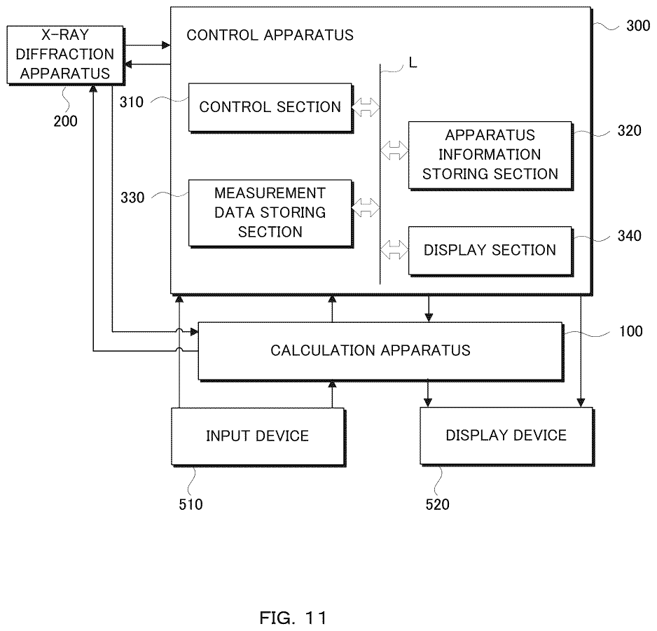

FIG. 11 is a block diagram showing an example of a configuration of the control apparatus 300. The control apparatus 300 is configured from a computer formed by connecting CPU, ROM, RAM and a memory to a bus. The control apparatus 300 may be a PC terminal or a server on the cloud. Not only the whole apparatus but also part of the apparatus or some functions of the apparatus may be provided on the cloud. The control apparatus 300 is connected to the X-ray diffraction apparatus 200 to receive information.

The control apparatus 300 comprises the control section 310, the apparatus information storing section 320, the measurement data storage section 330, and the display section 340. Each section can transmit and receive information via the control bus L. When the calculation apparatus 100 and the control apparatus 300 are structurally separate, the input device 510 and the display device 520 are connected to CPU of the control apparatus 300 via an appropriate interface. In this case, the input device 510 and the display device 520 may be different from those connected to the calculation apparatus 100.

The control section 310 controls the operations of the X-ray diffraction apparatus 200. The apparatus information storing section 320 stores apparatus information acquired from the X-ray diffraction apparatus 200. The apparatus information may include information about the X-ray diffraction apparatus 200, such as apparatus name, source type, wavelength, background, etc.

The measurement data storing section 330 stores the measurement data acquired from the X-ray diffraction apparatus 200. In addition to the measurement data, necessary information among information on the X-ray diffraction apparatus 200 such as the source type, the wavelength, and the background, the shape and the arrangement the type of the constituent elements, the composition and the absorption coefficient of the sample may be stored. The display section 340 causes the display device 520 to display measurement data and the like. Thus, the measurement data, etc. can be checked by a user. In addition, the user can instruct and designate the control apparatus 300, the calculation apparatus 100 and the like based on the measurement data and the like.

Note that the calculation apparatus 100 may be configured as a part of functions included in the control apparatus 300. In addition, the calculation apparatus 100 and the control apparatus 300 may be configured as an integrated apparatus.

### [Measurement Method]

A sample is placed in the X-ray diffraction apparatus 200, and X-rays are made to enter the sample under the control of the control apparatus 300, and diffracted X-rays or the like generated from the sample are detected. If necessary, the sample stage or the goniometer is driven under a predetermined condition. Thus, measurement data such as total scattering data is acquired. The X-ray diffraction apparatus 200 transmits the acquired measurement data, the necessary apparatus information and the like to the control apparatus 300.

### [Generation Method of Structural Model]

A structural model that reproduces the measurement data is generated by the control apparatus 300, the calculation apparatus 100 or an external apparatus. The method for generating the structural model may be any method. The structural model can be given as data showing a finite atomic (molecular) arrangement in, for example, a cube, a cuboid, or a parallel hexahedron, depending on the sample. A structural model showing the atomic arrangement in such a finite region is obtained, and the total scattering intensity is calculated from the structural model. Then, the structural model is modified until the degree of coincidence or the degree of deviation between the total scattering intensity of the structural model and the measurement data is better than the set value. The generation of the structural model is terminated at a stage when the degree of coincidence or the degree of deviation between the total scattering intensity of the structural model and the measurement data becomes better than the set value.

For example, when a structural model is generated by RMC method, the atomic arrangement of the structural model is varied randomly, and when the degree of coincidence or deviation after the operation is better than the degree of coincidence or deviation before the operation (the degree of closeness is large), further random variation is performed based on the atomic arrangement. On the other hand, when the degree of coincidence or deviation after the operation is not better than the degree of coincidence or deviation before the operation (the degree of closeness is not larger), the operation is cancelled, and the random variation is performed again from the atomic arrangement before the operation. Such an operation is performed until the degree of coincidence or deviation satisfies a predetermined condition. Incidentally, the method for generating the structural model may be an MD method (Molecular Dynamics method) or an MC method (Monte Carlo method).

Using the system 400 described above, measurement data can be obtained from the X-ray diffraction apparatus 200 and a structural model can be generated. Then, a correlation function can be calculated from the generated structural model.

### Example 1

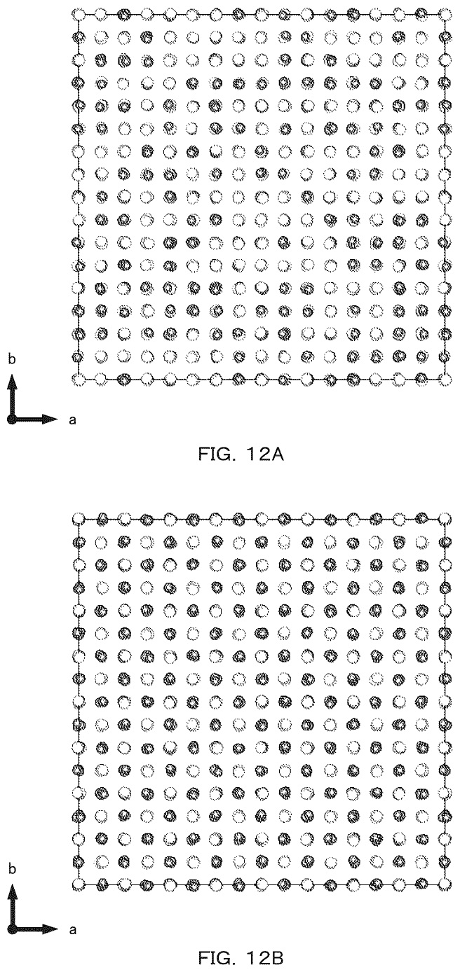

Using the calculation apparatus 100 configured as described above, two structural models with different atomic arrangement orders were generated, and it was verified whether or not the features of the atomic arrangement appeared in the correlation functions calculated from the structural models. Specifically, the following was performed. Lattice points with a distance of 3.0 Å between the adjacent points in the side, plane and inside of a cube with one side of 24 Å in a three-dimensional space, were set. Next, a structural model where Ne and Ar were randomly arranged at a ratio of 1:1 on the lattice points was formed. In addition, a structural model where Ne and Ar are alternately arranged at the same lattice points was formed. A displacement of Δr≤0.2 Å was randomly given to the particles (Ne or Ar) of each structural model, and the structural model in which they were randomly arranged was designated structural model 1, and the structural model in which they were alternately arranged was designated structural model 2. FIGS. 12A and 12B are schematic diagrams showing exemplary states of structural model 1 and structural model 2, respectively.

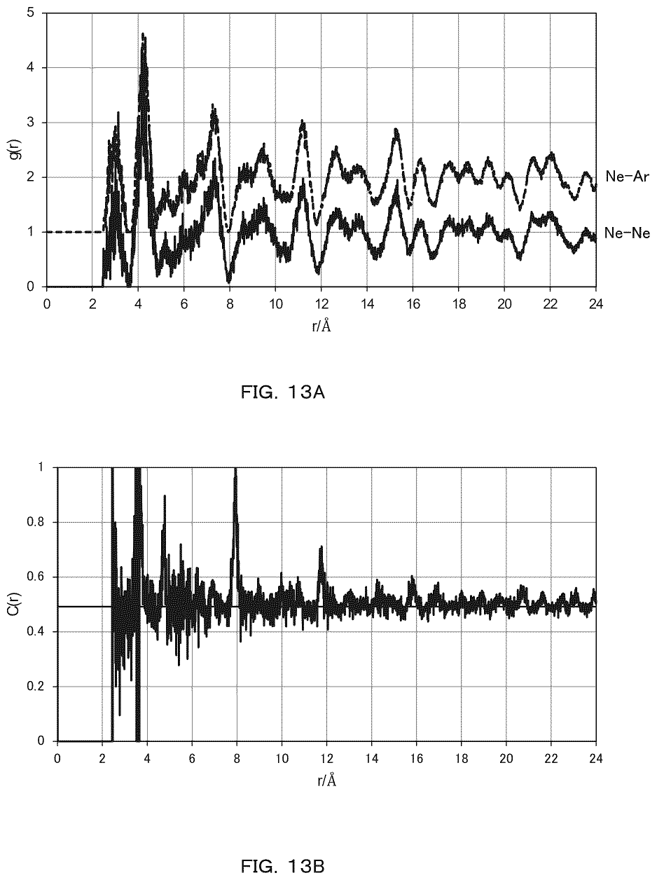

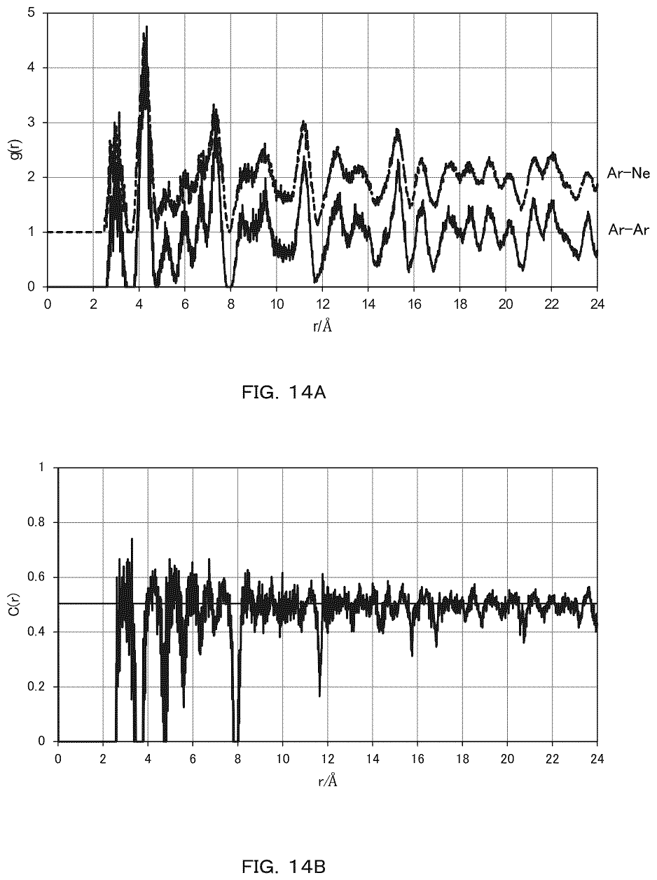

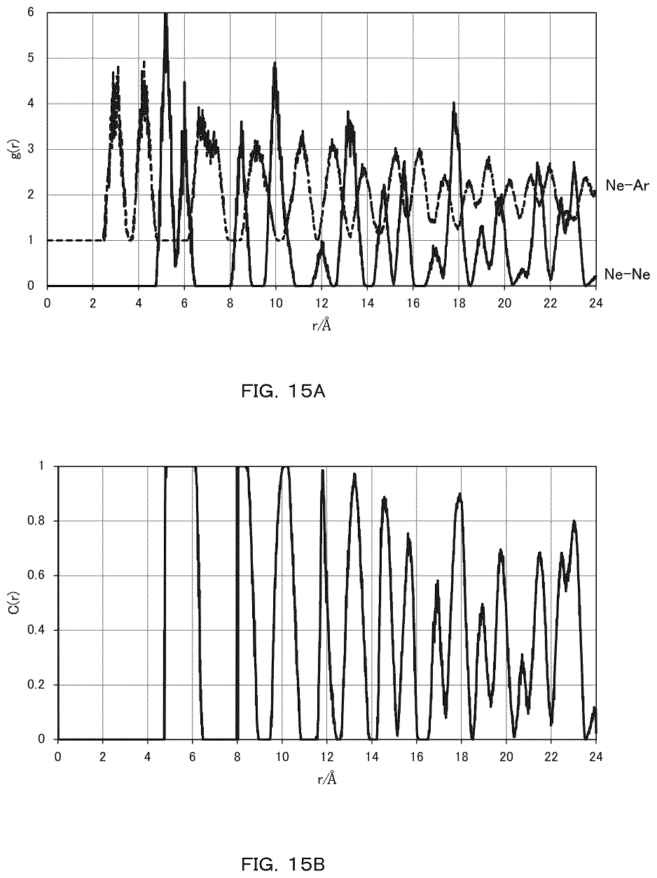

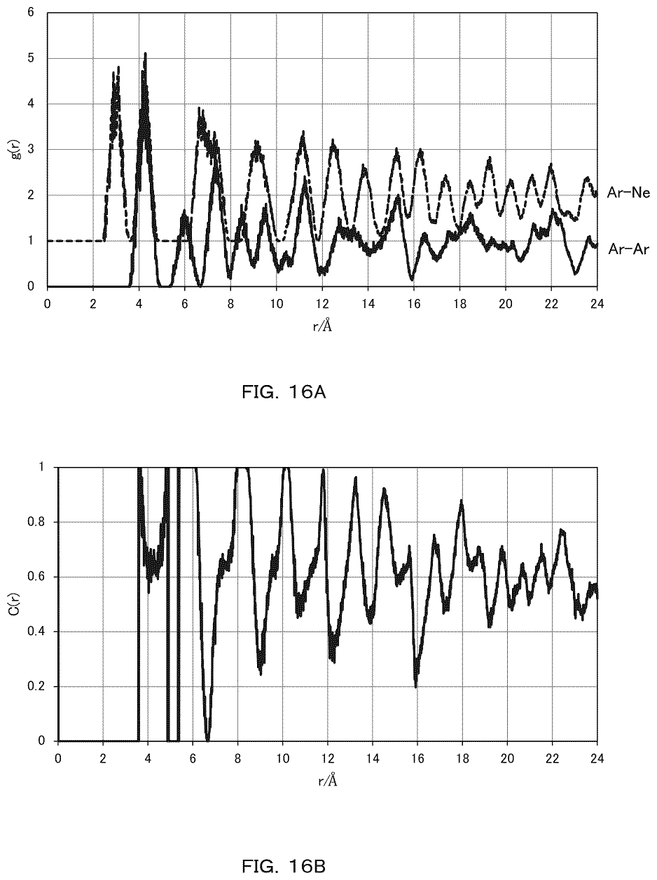

Next, using the calculation apparatus 100, specific atomic species were set for structural model 1 and structural model 2, and the first pair distribution function, the second pair distribution function, and the correlation function were calculated. FIGS. 13A and 13B are graphs of the pair distribution function and the correlation function, respectively, where Ne of structural model 1 is a specific atomic species. FIGS. 14A and 14B are graphs of the pair distribution function and the correlation function, respectively, where Ar of structural model 1 is a specific atomic species. In addition, FIGS. 15A and 15B are graphs of the pair distribution function and the correlation function, respectively, where Ne of structural model 2 is a specific atomic species. FIGS. 16A and 16B are graphs of the pair distribution function and the correlation function, respectively, where Ar of structural model 2 is a specific atomic species.

In FIGS. 13A and 15A, Ne—Ne indicates the first pair distribution function when Ne is a specific atomic species, and Ne—Ar indicates the second pair distribution function when Ne is a specific atomic species. Further, in FIGS. 14A and 16A, Ar—Ar indicates the first pair distribution function when Ar is a specific atomic species, and Ar—Ne indicates the second pair distribution function when Ar is a specific atomic species. All are shown to be shifted in the vertical axis direction.

The correlation function C(r) of FIGS. 13B and 14B shows that the baseline of the correlation function C(r) corresponds to the atomic ratio of the specific atomic species in the structural model (the ratio of the specific atomic species occupying in the structural model, which is the mean concentration) for structural model 1 with two types of atoms arranged randomly. Note that a straight line drawn at C(r)=0.5 in FIGS. 13B and 14B indicates the atomic ratio of the specific atomic species. The correlation function C(r) represents the abundance ratio of the specific atomic species at a correlation distance r from the specific atomic species. That is, a peak in the correlation function C(r) indicates that there are many sets of specific atomic species and specific atomic species in the correlation distance. By displaying the atomic ratio of the specific atomic species and the correlation function C(r) on the same graph, it is possible to determine at which correlation distance r a regular arrangement occurs. Further, the regularity of the atomic arrangement may be determined based on the correlation function C(r) and the atomic ratio of the specific atomic species. For example, when the deviation between the correlation function C(r) and the atomic ratio of a specific atomic species is a certain value or more, it may be determined that the deviation is regular.

In the case of structural model 1 in which two types of atoms are randomly arranged, the fluctuation ranges of the correlation function C(r) in FIGS. 13B and 14B are small, and it is found that the fluctuation ranges converge in a region where the correlation distance r is about 10 Å or more. On the other hand, in the case of structural model 2 in which two types of atoms are arranged alternately and regularly, the fluctuation ranges of the correlation function C in FIGS. 15B and 16B are large, and the fluctuation ranges do not converge even in an area where the correlation distance r is 20 Å or more. From this, it can be seen that atoms in the structural model are regularly arranged even at a correlation distance of 20 Å or more.

The variance is also used to express the fluctuation width of the correlation function C(r) as an index. The variances of the correlation function C(r) for structural model 1 were 0.007 and 0.012 for Ne and Ar as the specific atomic species, respectively. On the other hand, the variances of the correlations C(r) for structural model 2 were 0.045 and 0.126 for Ne and Ar as the specified atomic species, respectively. The large variance of structural model 2 indicates that atoms are regularly arranged in structural model 2. That is, the regularity of the atomic arrangement can be determined by using the variance as an index. Here, in order to improve the calculation accuracy, the calculation range of the variance was calculated excluding the range of C(r)=0. Note that the same effect can be obtained by using the standard deviation instead of the variance.

As a result of Example 1, it was confirmed that the regularity of the atomic arrangement in the structural model appears in the correlation function in the case of the structural model in which the presence or absence of the regularity of the structural model is clear.

### Example 2

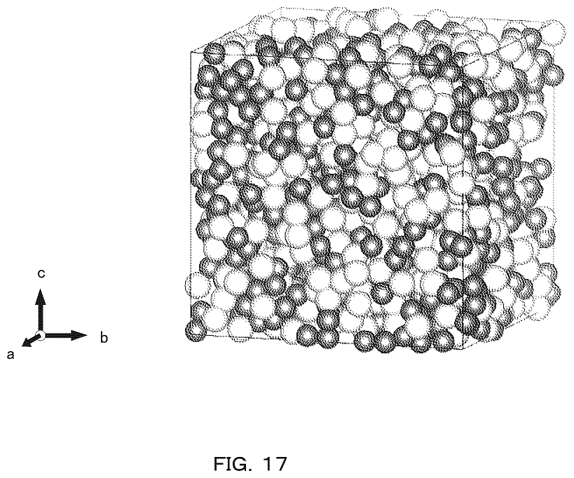

Using the calculation apparatus 100 configured as described above, it was verified whether or not the features of the atomic arrangement appear in the correlation function assuming the atomic arrangement in which the position of the atom is not limited to the lattice point. Specifically, the following was performed. A structural model where Ne and Ar are randomly arranged at a ratio of 1:1 in a cube of 20 Å on one side in a three-dimensional space was formed. Then, the structural model where the particles of the structural model were moved by 10⁵MCSteps (Monte Carlo Steps) only with collision determination was designated as structural model 3. FIG. 17 is a schematic diagram showing an example of a state of structural model 3.

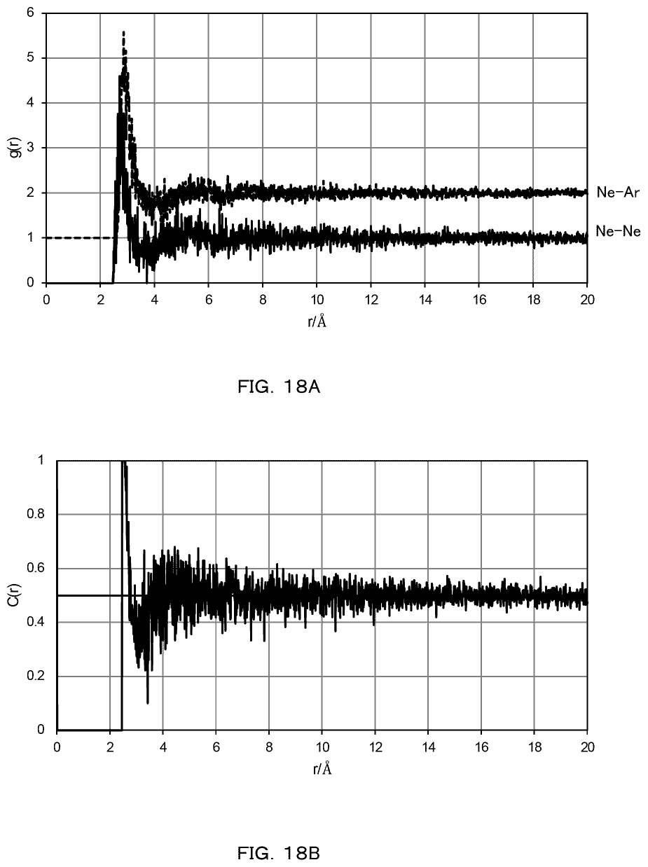

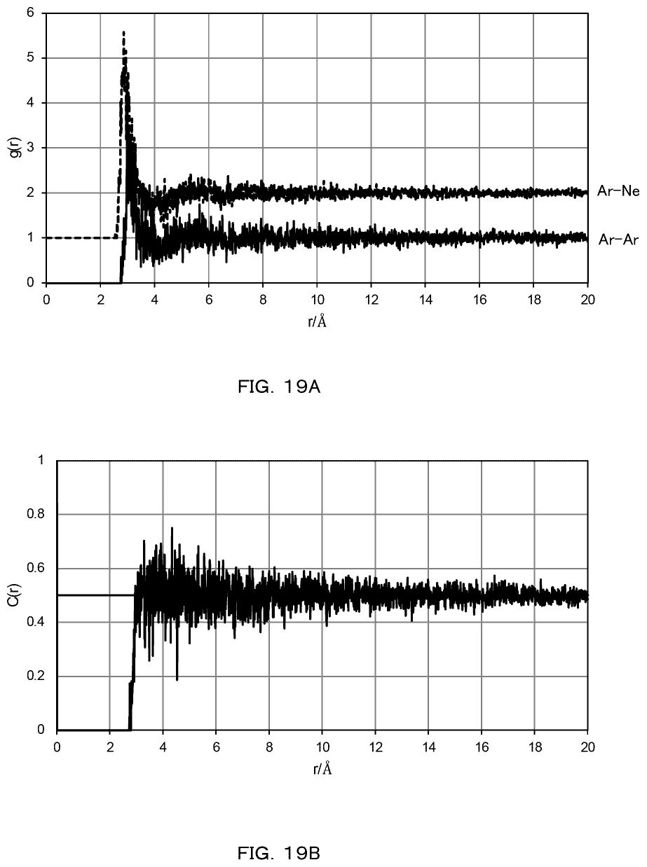

Next, a specific atomic species was set for structural model 3 using the calculation apparatus 100, and the first pair distribution function, the second pair distribution function and the correlation function were calculated. FIGS. 18A and 18B are graphs of the pair distribution function and the correlation function, respectively, where Ne of structural model 3 is a specific atomic species. FIGS. 19A and 14B are graphs of the pair distribution function and the correlation function, respectively, where Ar of structural model 3 is a specific atomic species. In FIG. 18A, Ne—Ne indicates the first pair distribution function when Ne is a specific atomic species, and Ne—Ar indicates the second pair distribution function when Ne is a specific atomic species. Further, in FIG. 19A, Ar—Ar indicates the first pair distribution function when Ar is a specific atomic species, and Ar—Ne indicates the second pair distribution function when Ar is a specific atomic species. All of them are shown to be shifted in the vertical axis direction.

From the correlation function C(r) of FIGS. 18B and 19B, it was found that the correlation function C(r) in the long-range converged to the atomic ratio of a specific atomic species in the case of structural model 3 in which two types of atoms were randomly arranged including the positions. Note that a straight line drawn at C(r)=0.5 in FIGS. 18B and 19B indicates the atomic ratio of the specific atomic species.

As a result of Examples 1 and 2, it was confirmed that information related to the mixing state can be obtained from the spatial correlation function of a specific atomic species.

### Example 3

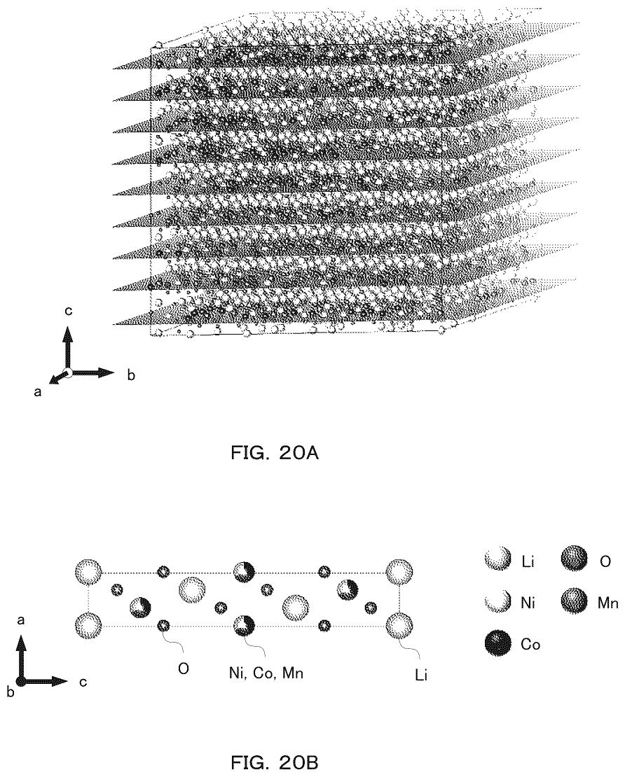

Crystal structural models describing the observed X-ray diffraction profiles were used to verify whether the correlation function provides information on the mixing state of neighboring particles. Specifically, crystal structural models (structural models) were prepared to describe the observed X-ray diffraction profiles of NCM333 (Li (Ni_{0.33}, CO_{0.33}, Mn_{0.33}) O₂) and NCM523 (Li (Ni_{0.5}, Co_{0.2}, Mn_{0.3}) O₂) used as positive electrode materials for Li ion-batteries. FIGS. 20A and 20B are schematic diagrams showing the crystallographic structural model and the unit cell of NCM333, respectively. As shown in FIG. 20A, NCM is configured of three types of sheet-structures consisting of only Li ions, only oxygen atoms, and only transition-metal elements. Further, as shown in FIG. 20B, in NCM333, the occupancy rates are allocated to the transition-metal-sites, and randomly present as the set occupancy rates basically. The same applies to NCM523.

In the structural model, Ni, Co and Mn were randomly arranged at transition-metal sites with Ni:Co:Mn=1:1:1 or 5:2:3 as the initial configuration of NCM333 or NCM523. Next, RMC steps were repeated until a profile approximating the observed X-ray diffraction and neutron diffraction profiles was obtained by substituting some Ni, Co and Mn with other elements (Ni, Co and Mn) while randomly changing the arrangement of Ni, Co and Mn by RMC method. Then, a structural model of NCM333, in which the profile sufficiently approximated to the observed X-ray diffraction and neutron diffraction profile was obtained, was indicated as structural model 4, and a structural model of NCM523, in which the profile sufficiently approximated to the observed X-ray diffraction and neutron diffraction profile was obtained, was indicated as structural model 5.

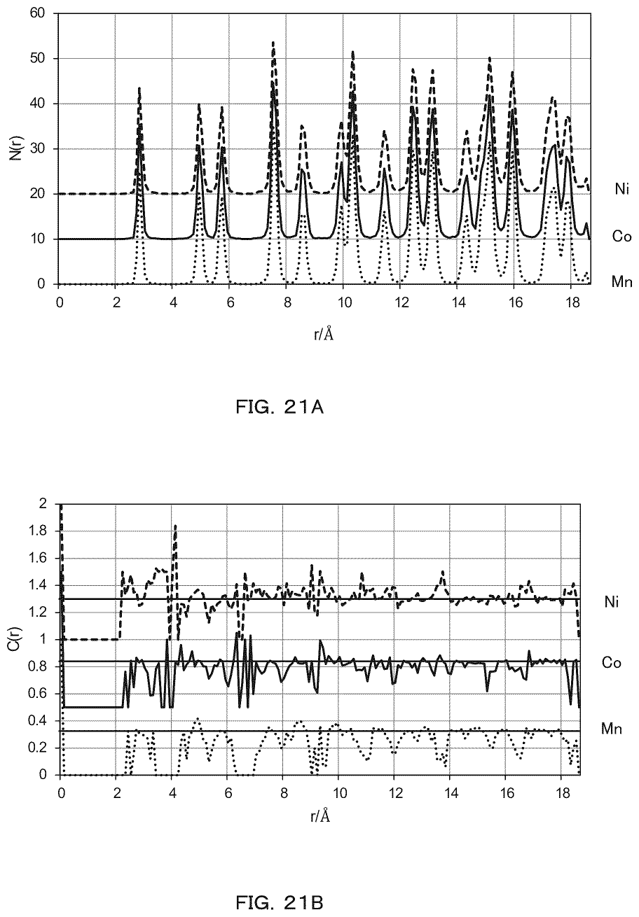

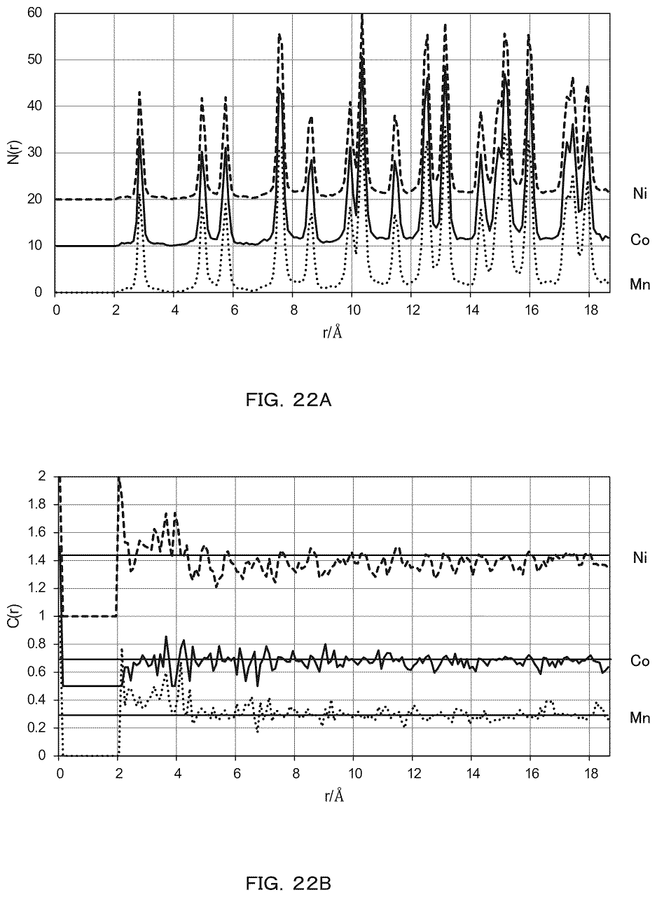

The calculation apparatus 100 was then used to determine specific planes of structural model 4 and structural model 5. Then, specific atomic species were set for structural model 4 and structural model 5, and the first radial distribution function, the second radial distribution function, and the correlation function were calculated. The specific plane was one plane of the sheet structures of transition metal elements only. FIGS. 21A and 21B are graphs of the first radial distribution function and the correlation function, respectively, where each of Ni, Co, Mn of structural model 4 is a specific atomic species. FIGS. 22A and 22B are graphs of the first radial distribution function and the correlation function, respectively, where each of Ni, Co, Mn of structural model 5 is a specific atomic species. All are shown to be shifted in the vertical axis direction. Note that Ni, Co and Mn were used as the two or more types of atomic species including a specific atomic species in the second radial distribution function in calculating the correlation function.

The atomic ratios (mean concentrations) of Ni, Co and Mn in a specific plane of structural model 4 were 0.33, 0.33, and 0.3, respectively. The lines drawn on the correlation functions in FIG. 21B show the atomic rations of specific atomic species, respectively. FIG. 21B shows that Co and Mn are likely to be randomly present at all distances in NCM333. On the other hand, it was proven that Ni was highly likely to form the cluster in the nearest neighbor.

The atomic ratios (mean concentrations) of Ni, Co and Mn of structural model 5 in a specific plane were 0.3, 0.2, and 0.43, respectively. The lines drawn on the correlation functions in FIG. 22B show the atomic ratios of specific atomic species, respectively. FIG. 22B shows that Co is likely to be randomly present at all distances in NCM523. On the other hand, it was proven that Ni and Mn were highly likely to form the cluster in the nearest neighbor.

As a result of Example 3, it was confirmed that whether the site replacement is random or regular could be examined in the case of the structural model in which the occupancy rate is set in the average structure.

From the above results, it was confirmed that the calculation apparatus, the method, and the program of the present disclosure can calculate the correlation function from the structural model. It was also confirmed that the correlation function can be evaluated.

Needless to say, the present disclosure is not limited to the above-described embodiments. The scope of the present disclosure covers various modifications and equivalents included in the technical idea of the present disclosure. In addition, the names, structures, shapes, numbers, positions, sizes, and the like of the constituent elements shown in the drawings are for convenience of explanation and may be changed as appropriate.

The functionality of the elements disclosed in this specification may be implemented using general purpose processors, special purpose processors, integrated circuits, ASICs (Application Specific Integrated Circuits), FPGAS (Field Programmable Gate Arrays), conventional circuits, and/or circuitry or processing circuitry including combinations thereof that are programmed using one or more programs stored in one or more memories or otherwise configured to perform the disclosed functions. The processor can be regarded as a circuitry or a processing circuitry because it comprises transistors and other circuits. The processor may be a programmed processor that executes programs stored in memory. In this disclosure, a circuit, unit, or means is hardware that performs the recited functions or is hardware programmed to perform the recited functions. The hardware may be any hardware disclosed in this specification that is programmed or configured to perform the recited functions.

This application claims priority from Japanese Patent Application No. 2024-226055 filed on Dec. 23, 2024, the entire contents of Japanese Patent Application No. 2024-226055 are incorporated herein by reference.

### DESCRIPTION OF SYMBOLS

100 calculation apparatus
110 structural model acquiring section
120 atomic species setting section
125 plane determining section
130 correlation function calculating section
135 index calculating section
140 evaluation section
150 display section
200 X-ray diffraction apparatus
210 X-ray generating section
220 incident side optical unit
230 goniometer
240 sample stage
250 emitting side optical unit
260 detector
300 control apparatus
310 control section
320 apparatus information storing section
330 measurement data storing section
340 display section
400 system
510 input device
520 display device

What is claimed is:

1. A calculation apparatus for calculating a correlation function from a structural model, the calculation apparatus comprising:
processing circuitry configured to
acquire the structural model including a plurality of types of atoms in space,
set a specific atomic species in the structural model, and
calculate the correlation function that is a ratio between a first radial distribution function and a second radial distribution function,
wherein the first radial distribution function is a radial distribution function between atoms of the specific atomic species and atoms of the specific atomic species, and
the second radial distribution function is a radial distribution function between atoms of the specific atomic species and atoms of two or more types of atomic species including the specific atomic species.

2. The calculation apparatus according to claim 1,
wherein the processing circuitry is further configured to display the correlation function.

3. The calculation apparatus according to claim 2, wherein the processing circuitry is further configured to
display the correlation function and an atomic ratio of the specific atomic species in the structural model in an overlapping manner.

4. The calculation apparatus according to claim 2, wherein the processing circuitry is further configured to
simultaneously display the correlation function of the specific atomic species and the correlation function of an atomic species different from the specific atomic species.

5. The calculation apparatus according to claim 1, wherein the processing circuitry is further configured to
determine a specific plane in the structural model, and
calculate the correlation function in the specific plane.

6. The calculation apparatus according to claim 1, wherein the processing circuitry is further configured to
evaluate the regularity of the atomic arrangement in the structural model based on the correlation function.

7. The calculation apparatus according to claim 6, wherein the processing circuitry is further configured to
calculate an index based on the correlation function, and
evaluate the regularity of the atomic arrangement based on the index.

8. The calculation apparatus according to claim 7,
wherein the index is a variance or a standard deviation of the correlation function.

9. The calculation apparatus according to claim 7,
wherein the index is calculated based on the correlation function and an atomic ratio of the specific atomic species in the structural model.

10. The calculation apparatus according to claim 1,
wherein the structural model is a model generated by an RMC method.

11. A method for calculating a correlation function from a structural model, the method comprising:
acquiring the structural model including a plurality of types of atoms in space;
setting a specific atomic species in the structural model; and
calculating the correlation function that is a ratio between a first radial distribution function and a second radial distribution function,
wherein the first radial distribution function is a radial distribution function between atoms of the specific atomic species and atoms of the specific atomic species, and
the second radial distribution function is a radial distribution function between atoms of the specific atomic species and atoms of two or more types of atomic species including the specific atomic species.

12. A non-transitory computer readable recording medium having recorded thereon a program for calculating a correlation function from a structural model, the program causing a computer to execute a method, the method comprising:
acquiring the structural model including a plurality of types of atoms in space;
setting a specific atomic species in the structural model; and
calculating the correlation function that is a ratio between a first radial distribution function and a second radial distribution function,
wherein the first radial distribution function is a radial distribution function between atoms of the specific atomic species and atoms of the specific atomic species, and
the second radial distribution function is a radial distribution function between atoms of the specific atomic species and atoms of two or more types of atomic species including the specific atomic species.
